(19) United States
(12) Patent Application Publication
(10) Pub. No.: US 2022/0131288 A1
(43) Pub. Date: Apr. 28, 2022

(54) ELECTRICAL CONTROL PANEL FOR CONNECTOR TERMINALS, ELECTRICAL CONTROL CABINET, AND AIR CONDITIONER

(71) Applicant: Guangdong Giwee Technology Co., Ltd., Foshan (CN)

(72) Inventor: Feng Kaiqin, Foshan (CN)

(21) Appl. No.: 17/506,810

(22) Filed: Oct. 21, 2021

(30) Foreign Application Priority Data
Oct. 23, 2020 (CN) 202022395633.0

(51) Int. Cl. H01R 12/51; F24F 11/30; F24F 13/20

(52) U.S. Cl. CPC H01R 12/515; F24F 2013/207; F24F 13/20; F24F 11/30

(57) ABSTRACT

An electrical control panel for connector terminals, an electrical control cabinet, and an air conditioner, including: a motherboard body; a connector terminal body, the connector terminal body disposed on the motherboard body, at least one connector terminal body, a plurality of connection ports and control switches corresponding to the connection ports disposed on the connector terminal body, the connection ports connected to the components of the motherboard body through conducting wires, and the control switches act to compress or loosen the conducting wires. A connector terminal body is disposed on the motherboard body and the control switch can compress or loosen the conducting wire inserted into the connection port, reducing the number of hard connections, reducing the volume of the electrical control cabinet, lowering material costs, simplifying wiring, saving time, and reducing the cost of labor.

### FOREIGN PRIORITY

This application claims priority to Chinese Patent Application No. 202022395633.0, filed Oct. 23, 2020, and all the benefits accruing therefrom under 35 U.S.C. § 119, the contents of which in its entirety are herein incorporated by reference.

### TECHNICAL FIELD

This utility model relates to the technical field of air conditioning systems, and in particular to an electrical control panel for connector terminals, an electrical control cabinet, and an air conditioner.

### BACKGROUND

Air conditioning, or air conditioners, refer to devices regulating and controlling parameters such as the temperature, humidity, and flow of the air in a building or structure by man-made means.

Air conditioners are composed of four parts: a cooling system, an air duct system, an electrical system, and a cabinet and a panel. The cooling system is the refrigeration and cooling part of the air conditioner, and it is a sealed refrigeration cycle composed of a refrigeration compressor, a condenser, capillary tubes, an evaporator, a solenoid directional valve, a filter, and refrigerant. The air duct system is the part of the air conditioner that accelerates the heat exchange of air, and it is composed of devices such as a centrifugal blower and an axial flow fan. The electrical system is the part in the air conditioner that controls the temperature and causes the compressor and fan to operate safely, and it is composed of a motor, a thermostat, a relay, a capacitor, and a heater. The cabinet and panel are the air conditioner's framework, various components and supports, and parts directing the airflow, and they are composed of a cabinet, a panel, and louvers.

However, the sockets disposed on the motherboard body of a traditional air conditioner require providing extra terminal blocks matched to the sockets, and they require custom-made wiring sets to connect the sockets to the terminal blocks. The addition of terminal blocks means increased electrical control cabinet volume, which leads to additional costs.

### SUMMARY

The objective of the embodiments of this utility model is: to provide an electrical control panel for connector terminals, an electrical control cabinet, and an air conditioner, with the aim of resolving the problem of the sockets disposed on the motherboard body of traditional air conditioners requiring the addition of extra terminal blocks and requiring custom-made wiring sets, increasing electrical control cabinet volume and thereby increasing costs.

In order to achieve this goal, this utility model employs the following technical scheme: providing an electrical control panel for connector terminals, including: a motherboard body; a connector terminal body, wherein the connector terminal body is disposed on the motherboard body, there is at least one connector terminal body, a plurality of connection ports and control switches corresponding to the connection ports are disposed on the connector terminal body, the connection ports are connected to the components of the motherboard body through conducting wires, and the control switches act to compress or loosen the conducting wires.

Furthermore, a strong current area and/or weak current area are disposed on the motherboard body, and if the strong current area and the weak current area are simultaneously present, the strong current area and the weak current area are spaced apart, and the strong current area and the weak current area each have a connector terminal body.

Furthermore, a strong current wire terminal is disposed on the strong current area, and a weak current wire terminal is disposed on the weak current area.

Furthermore, the control switch on the connector terminal body may be a lever-style switch, the connector terminal body has an in-use position and an idle position, when the control switch is in the in-use position, the wire inserted into the connector terminal is in a compressed state, and when the control switch is in the idle position, the wire inserted into the connector terminal is in a loosened state.

An electrical control cabinet, including a cabinet body and the electrical control panel for connector terminals according to any of the above items; the cabinet body has a holding cavity, a plurality of clamping blocks are disposed on the inner wall of the holding cavity, and the plurality of clamping blocks are distributed around the motherboard body and are fitted with the motherboard body, such that the motherboard body is connected to the cabinet body.

Furthermore, the clamping blocks include a first clamping block and a second clamping block located at opposite ends of the motherboard body; the clamping blocks have clamping slots, and the side walls of the motherboard body are clamped inside the clamping slots.

Furthermore, sliding grooves are disposed on the inner wall of the holding cavity, the sliding grooves are distributed along the axis of the holding cavity, and the first clamping block is slidably connected inside the sliding grooves.

Furthermore, springs are disposed within the sliding grooves, and the ends of the spring are connected to the sliding groove and the first clamping block.

An air conditioner, including: A plurality of connector terminal electrical control panels according to any of the above items, and; a plurality of electrical control cabinets according to any of the above items.

Compared to prior art, the benefits of this utility model are: A connector terminal body is disposed on the motherboard body of this utility model, and the control switch can compress or loosen the conducting wire inserted into the connection port, reducing the number of hard connections, reducing the volume of the electrical control cabinet, lowering material costs, simplifying wiring, saving time, and reducing the cost of labor.

### BRIEF DESCRIPTION OF THE DRAWINGS

The following is a more detailed description of this utility model based on the drawings and embodiments.

FIG. 1 is a schematic diagram of an electrical control panel for connector terminals, an electrical control cabinet and an air conditioner of an embodiment of this utility model.

FIG. 2 is a schematic diagram of the body of the electrical control panel for connector terminals, the electrical control cabinet and the body of the connector terminals of the air conditioner of an embodiment of this utility model.

FIG. 3 is a schematic diagram of a clamping block of the control panel for connector terminals, the electrical control cabinet and the air conditioner of an embodiment of this utility model.

FIG. 4 is a schematic diagram, from another angle, of the clamping block of the control panel for connector terminals, the electrical control cabinet and the air conditioner of an embodiment of this utility model.

In the figures: 100, motherboard body; 200, connector terminal body; 201, connection port; 202, control switch; 300, electrical control cabinet; 301, clamping slot; 302, sliding groove; 303, clamping block.

### DETAILED DESCRIPTION

In order to clarify the technical problem addressed, the technical schemes employed, and the technical effects achieved by this utility model, the technical schemes of the embodiments of this utility model are described in further detail below. Clearly, the embodiments described are merely a portion of the embodiments of this utility model, and are not all of the embodiments. All other embodiments based on the embodiments of this utility model and obtained by a person skilled in the art without the expenditure of creative labor shall fall within the scope of protection of this utility model.

In the descriptions of this utility model, unless otherwise explicitly stipulated and defined, the terms “linked”, “connected”, and “fixed” should be broadly interpreted. For example, it can be a fixed connection or a detachable connection, or it can form one integrated body. It can be a mechanical connection or an electrical connection. It can be direct linkage or indirectly through an intermediary element. It can be the internal linkage of two elements or an interactive relationship between two elements. For persons having ordinary skill in the art, the specific meaning of these terms in this utility model can be understood based on the specific circumstances.

In this utility model, unless otherwise explicitly stipulated and defined, when a first feature is “above” or “below” a second feature, it can include direct contact between the first and second features, and it can also include the first and second feature not being in direct contact but being in contact through another feature between them. Also, a first feature being “on top of”, “on”, and “above” a second feature includes the first feature being directly above and diagonally above the second feature, or it merely indicates that the height of the first feature is higher than the second feature. The first feature being “beneath”, “under” and “below” the second feature includes the first feature being directly below and diagonally below the second feature, or it merely indicates that the height of the first feature is lower than the second feature.

The sockets disposed on the motherboard body of a traditional air conditioner require providing extra terminal blocks matched to the sockets, and they require custom-made wiring sets to connect the sockets to the terminal blocks. The addition of terminal blocks means increased electrical control cabinet volume, which leads to additional costs.

This utility model replaces sockets connected to terminal blocks with a connector terminal body 200, and the control switch 202 can compress or loosen the conducting wire inserted into the connection port 201, reducing the number of hard connections, reducing the volume of the electrical control cabinet 300, lowering material costs, simplifying wiring, saving time, and reducing the cost of labor.

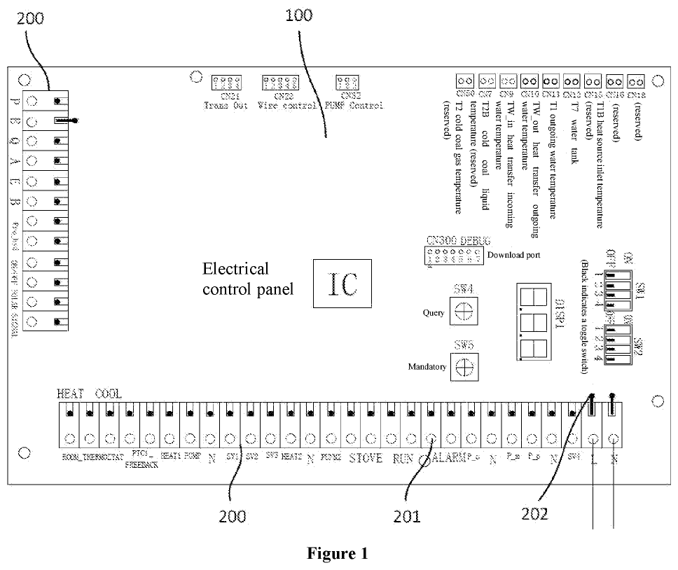

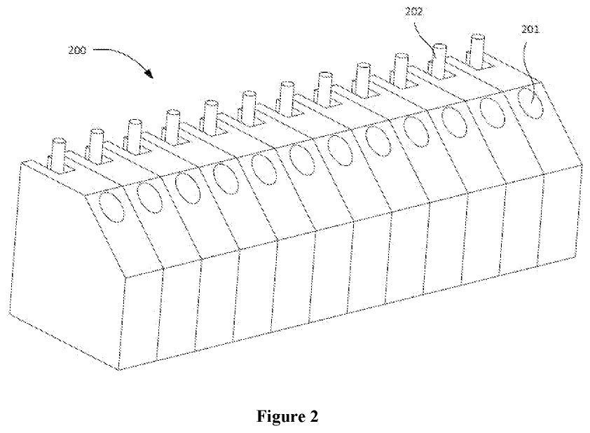

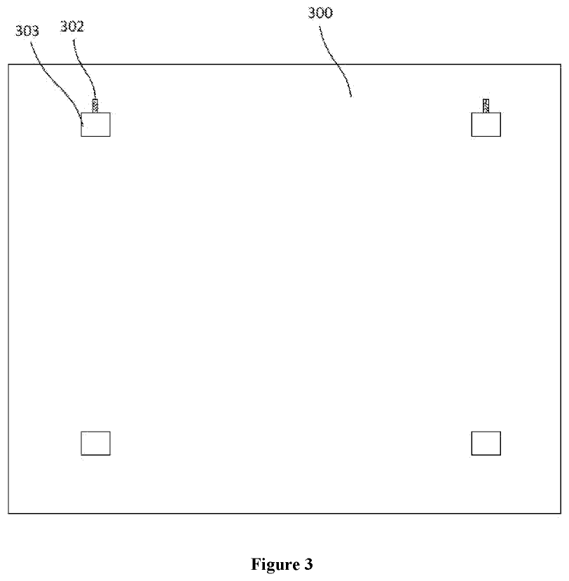

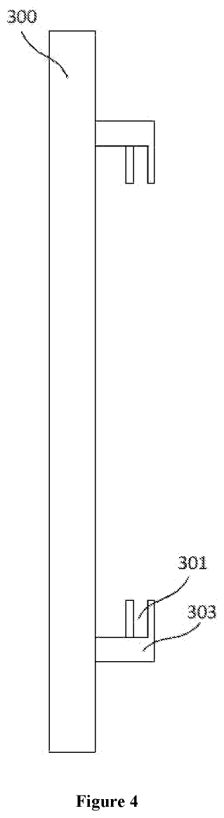

In this utility model, FIG. 1 is a schematic diagram of an electrical control panel for connector terminals, an electrical control cabinet 300 and the air conditioner; FIG. 2 is a schematic diagram of the connector terminal body 200 of the control panel for connector terminals, the electrical control cabinet 300 and the air conditioner body; FIG. 3 is a schematic diagram of the clamping block 303 of the control panel for connector terminals, the electrical control cabinet 300 and the air conditioner; FIG. 4 is a schematic diagram, from another angle, of the clamping block 303 of the control panel for connector terminals, the electrical control cabinet 300 and the air conditioner.

As shown in FIG. 1, this embodiment provides an electrical control panel for connector terminals, including: a motherboard body 100; a connector terminal body 200, wherein the connector terminal body 200 is disposed on the motherboard body 100, there is at least one connector terminal body 200, a plurality of connection ports 201 and control switches 202 corresponding to the connection ports 201 are disposed on the connector terminal body 200, the connection ports 201 are connected to the components of the motherboard body 100 through conducting wires, and the control switches 202 act to compress or loosen the conducting wires.

In this utility model, the preferred model of the connector terminal body 200 is HP-T6003, rated 300V, 8A; the diameter of the conducting wire inserted into the connection port 201 is 0.3-0.75 mm; PA66 is used as the material of the connector terminal body 200.

It can be understood that the connector terminal body 200 is soldered to the motherboard body 100, the connector terminal body 200 employs a base plate-style terminal block, the connection port 201 on the connector terminal body 200 corresponds to the control switch 202, the connector terminal body 200 has an in-use position and an idle position, when the control switch 202 is in the in-use position, the conducting wire inserted into the connection port 201 is in a compressed state, and when the control switch 202 is in the idle position, the conducting wire inserted into access the connection port 201 is in a loosened state.

When the connector terminal body 200 is disposed axially or longitudinally along the motherboard body 100, and it is correspondingly connected to the components on the motherboard body 100, it can be understood that compared to having sockets on a traditional motherboard body 100, wherein the sockets must be equipped with matching terminal blocks, the connector terminal is characterized by reducing the number of hard connections, reducing the size of the electrical control cabinet 300, lowering material costs, simplifying wiring, saving time, and reducing the cost of labor.

In this utility model, a strong current area and/or weak current area are disposed on the motherboard body 100, and if both the strong current area and the weak current area are present, the strong current area and the weak current area are spaced apart, and the strong current area and the weak current area each has a connector terminal body 200.

When a strong current area and a weak current area are disposed on the motherboard body 100, maximizing the distance between the strong current area and the weak current area can achieve the separation of the strong current area and the weak current area connected to the motherboard body 100, thereby avoiding signal interference, improving the stability of the air conditioner's operation, and eliminating safety hazards.

Furthermore, a strong current wire terminal is disposed on the strong current area, and a weak current wire terminal is disposed on the weak current area.

Specifically, the strong current area has other components such as relays, the weak current area has circuits or components such as communication circuits, and the strong current wire terminal and weak current wire terminal have corresponding connector terminals; the strong current wire terminal and weak current wire terminal are spaced apart, to avoid interference between the strong and weak current elements and improve operational stability.

Here, the control switch 202 on the connector terminal body 200 may be a lever-style switch, the connector terminal body 200 has an in-use position and an idle position, when the control switch 202 is in the in-use position, the wire inserted into the connector terminal is in a compressed state, and when the control switch 202 is in the idle position, the wire inserted into the connector terminal is in a loosened state.

It can be understood that the connector terminal body 200 must be able to withstand high temperatures in the preheating zone and temperatures conducted to the connector terminal body 200 through wave soldering throughout the entire assembly process; solder must not affect the connector terminal body 200, it must be easily removed, and there must be no residue.

An electrical control cabinet 300, including a cabinet body and the electrical control panel for connector terminals according to any of the above items; the cabinet body has a holding cavity, a plurality of clamping blocks are disposed on the inner wall of the holding cavity 303, and the plurality of clamping blocks 303 are distributed around the motherboard body 100 and are fitted with the motherboard body 100, such that the motherboard body 100 is connected to the cabinet body.

The clamping blocks 303 are disposed on the inner walls of the side plates of the holding cavity. In this embodiment, there can be four clamping blocks 303, and the four clamping blocks 303 are positioned at the four right angles of the motherboard body 100.

It can be understood that there can also be three clamping blocks 303, with the three clamping blocks 303 disposed around the motherboard body 100, and the clamping blocks 303 disposed at the side walls of the motherboard body 100. One clamping block 303 can be disposed at the middle of the upper end of the motherboard body 100, and two clamping blocks 303 can be disposed at the lower end of the motherboard body 100.

The distance between the clamping block 303 located at the upper end of the motherboard body 100 and the clamping blocks 303 located at the lower end of the motherboard body 100 is not greater than the distance between the upper and lower ends of the motherboard body 100, ensuring that the clamping block 303 can clamp the motherboard body 100 inside the electrical control cabinet 300.

Furthermore, the clamping blocks 303 include a first clamping block and a second clamping block located at opposite ends of the motherboard body 100, the clamping blocks 303 have clamping slots 301, and the side walls of the motherboard body 100 are clamped inside the clamping slots 301.

Specifically, the first clamping block and the second clamping block both have a clamping slot 301, the clamping slot 301 is U-shaped, and the opening of the clamping slot 301 is disposed in the direction of the side wall of the motherboard body 100.

The radius of the opening of the clamping slot 301 is not less than the thickness of the motherboard body 100, and when the motherboard body 100 is disposed within the clamping slot 301, there is a certain space between the motherboard body 100 and the inner walls of the electrical control cabinet 300, ensuring the safe use of the motherboard body 100 and anti-interference capability.

In this utility model, sliding grooves 302 are disposed on the inner wall of the holding cavity, the sliding grooves 302 are distributed along the axis of the holding cavity, and the first clamping block is slidably connected inside the sliding grooves 302.

As shown in FIG. 3, the number of sliding grooves 302 is set as needed, and there can be one or two. In this embodiment, two sliding grooves 302 are employed, and the two sliding grooves 302 located on the same side of the motherboard body 100 are positioned on the same horizontal line.

It can be understood that the clamping blocks 303 located on the same side of the motherboard body 100 are both positioned on the same horizontal line, such that when the motherboard body 100 is disposed within the clamping slots 301, it will not tilt.

Furthermore, springs are disposed within the sliding grooves 302, and the ends of the springs are connected to the sliding grooves (302) and the first clamping block.

Specifically, when there are springs between the sliding grooves 302 and the first clamping block, the springs are in their original state or a slightly compressed state. In a more advantageous scheme, when there are springs between the sliding grooves 302 and the first clamping block, the springs are in a slightly compressed state, which can more tightly clamp the motherboard body 100.

An air conditioner, including: A plurality of connector terminal electrical control panels according to any of the above items, and; a plurality of electrical control cabinets 300 according to any of the above items.

In the descriptions herein, it must be understood that terms of an orientational or positional relationship such as “above”, “below”, “left”, and “right” are used solely to facilitate description and simplify operation, and do not indicate or imply that the referenced equipment or elements must have a specific orientation or be constructed and operated at a specific orientation; therefore, they must not be interpreted as limiting this utility model. In addition, the terms “first” and “second” are merely used to provide descriptive differentiation and have no special implications.

In the descriptions of this Specification, the reference terms “one embodiment” and “example” mean that a specific characteristic, structure, material, or feature described by the embodiment or example is contained within at least one embodiment or example of this utility model. In this Specification, illustrative expressions of these terms do not necessarily refer to the same embodiment or example.

In addition, it should be understood that, even though this Specification provides descriptions by means of implementation, it is not the case that every implementation contains only one independent technical scheme. This narrative form of the Specification is merely for the sake of clarity. A person skilled in the art should take the Specification as a whole. The technical schemes in the various embodiments may be appropriately combined, to form other implementations understandable to a person skilled in the art.

In combination with specific embodiments, the above describes the technical principles of this utility model. These descriptions are solely for the purpose of explaining the principles of this utility model, and must not, by any means, be interpreted as limiting the scope of protection of this utility model. Based on the explanations herein, a person skilled in the art may think of other specific implementations of this utility model with no expenditure of creative labor; these implementations shall fall within the scope of protection of this utility model.

What is claimed is:

1. An electrical control panel for connector terminals, characterized in that the electrical control panel for connector terminals comprises:
a motherboard body (100);
a connector terminal body (200), wherein the connector terminal body (200) is disposed on the motherboard body (100), there is at least one connector terminal body (200), a plurality of connection ports (201) and control switches (202) corresponding to the connection ports (201) are disposed on the connector terminal body (200), the connection ports (201) are connected to the components of the motherboard body (100) through conducting wires, and the control switches (202) act to compress or loosen the conducting wire.

2. The electrical control panel for connector terminals according to claim 1, characterized in that a strong current area and/or a weak current area are disposed on the motherboard body (100), and if both the strong current area and the weak current area are present, the strong current area and the weak current area are spaced apart, and the strong current area and the weak current area each has a connector terminal body (200).

3. The electrical control panel for connector terminals, the electrical control cabinet and the air conditioner according to claim 2, characterized in that a strong current wire terminal is disposed on the strong current area, and a weak current wire terminal is disposed on the weak current area.

4. The electrical control panel for connector terminals according to claim 1, characterized in that the control switch (202) on the connector terminal body (200) may be a lever-style switch, the connector terminal body (200) has an in-use position and an idle position, when the control switch (202) is in the in-use position, the wire inserted into the connector terminal (201) is in a compressed state, and when the control switch (202) is in the idle position, the wire inserted into the connector terminal (201) is in a loosened state.

5. An electrical control cabinet (300), characterized in that the electrical control cabinet (300) comprises a cabinet body and the electrical control panel for connector terminals according to claim 1; the cabinet body has a holding cavity, a plurality of clamping blocks (303) are disposed on the inner wall of the holding cavity, and the plurality of clamping blocks (303) are distributed around the motherboard body (100) and are fitted with the motherboard body (100), such that the motherboard body (100) is connected to the cabinet body.

6. The electrical control cabinet (300) according to claim 5, characterized in that the clamping blocks (303) comprise a first clamping block and a second clamping block located at opposite ends of the motherboard body (100), the clamping blocks (303) have clamping slots (301), and the side walls of the motherboard body (100) are clamped inside the clamping slots (301).

7. The electrical control cabinet (300) according to claim 6, characterized in that sliding grooves (302) are disposed on the inner wall of the holding cavity, the sliding grooves (302) are distributed along the axis of the holding cavity, and the first clamping block (303) is slidably connected inside the sliding grooves (302).

8. The electrical control cabinet (300) according to claim 7, characterized in that springs are disposed within the sliding grooves (302), and the ends of the springs are connected to the sliding grooves (302) and the first clamping block (303).

9. An air conditioner, characterized in that it comprises:
a plurality of the electrical control panels for connector terminals according to claim 1.
